(19) United States
(12) Patent Application Publication
(10) Pub. No.: US 2006/0243978 A1
(43) Pub. Date: Nov. 2, 2006

(54) Semiconductor device and method of manufacturing the same

(75) Inventors: Mikio Wakamiya, Yokkaichi (JP); Junichi Shiozawa, Yokkaichi (JP); Hirofumi Inoue, Kamakura (JP); Mitsuru Sato, Yokohama (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/412,921

(22) Filed: Apr. 28, 2006

(30) Foreign Application Priority Data
Apr. 28, 2005 (JP) 2005-132162

(51) Int. Cl. H01L 29/04

(52) U.S. Cl. 257/59

(57) ABSTRACT

A semiconductor device includes an amorphous silicon film having a principal plane and an insulating film formed by supplying radical oxygen onto the principal plane of the amorphous silicon film.

### CROSS-REFERENCE TO RELATED APPLICATIONS

This application is based upon and claims the benefit of priority from the prior Japanese Patent Application No. 2005-132162, filed on Apr. 28, 2005, the entire contents of which are incorporated herein by reference.

### BACKGROUND OF THE INVENTION

1. Field of the Invention

The present invention relates to a semiconductor device provided with a structure that an insulating film is formed on a principal plane of an amorphous silicon film and a method of manufacturing the same.

2. Description of the Related Art

An amorphous silicon film generally has a higher surface planarity as compared with a polycrystalline silicon film. When the planarity is high, occurrence of electric field concentration due to surface irregularity can be suppressed such that electric current flowing into an interface between films can be suppressed. Accordingly, an amorphous silicon film is sometimes used when a leak current characteristic regarding current flowing into the interface needs to be improved in the fabrication of a semiconductor device.

However, the amorphous silicon film is heat-sensitive. For example, the amorphous silicon film is crystallized into a polycrystalline silicon film when the amorphous silicon film is processed through a thermal process at or above 700° C. or when a thermal oxidation film is formed directly on the amorphous silicon film. Thus, due caution needs to be exercised when an oxide film is formed on the amorphous silicon film. For example, JP-A-H09-266318 discloses a method of forming an oxide film on an amorphous silicon film by a chemical vapor deposition (CVD) method. According to the disclosed method, a thin amorphous silicon film is formed on an oxide film by the CVD method. Excimer laser is irradiated on the amorphous silicon so that the thin amorphous silicon film is crystallized. An oxide film serving as a gate insulating film is formed on the crystallized amorphous silicon film by the CVD method.

When the oxide film is deposited on the amorphous silicon film by the CVD method, film density is rendered lower as compared with a film formed by a thermal oxidation method. Furthermore, an amount of leak current is increased since impurities of source gas composition remains in the film. Consequently, a completed device has a low dielectric breakdown voltage when the aforementioned oxide film is applied to a gate insulating film of a transistor, for example.

### BRIEF SUMMARY OF THE INVENTION

Therefore, an object of the present invention is to provide a semiconductor device which can suppress leak current flowing through an interface even when an oxide film is deposited on the amorphous silicon film and a method of manufacturing the same.

In one aspect, the present invention provides a semiconductor device comprising an amorphous silicon film having a principal plane and an insulating film formed by supplying radical oxygen onto the principal plane of the amorphous silicon film.

The invention further provides a semiconductor device comprising a semiconductor substrate, a gate insulating film formed on the semiconductor substrate, a floating gate electrode formed on the gate insulating film and made from an amorphous silicon, and an interpoly insulating film formed on the floating gate electrode. In the device, the floating gate electrode and the interpoly insulating film have an interface therebetween which is formed so as to have irregularities not greater than 10 nm.

In another aspect, the invention provides a method of manufacturing a semiconductor device, comprising forming an insulating film by supplying radical oxygen onto a principal surface of an amorphous silicon film at a temperature lower than a crystallization temperature of the amorphous silicon film, the amorphous silicon film constituting the semiconductor device.

The invention further provides a method of manufacturing a semiconductor device, comprising forming a first insulating film on a semiconductor substrate, forming an amorphous silicon film serving as a floating gate electrode on the first insulating film, and forming a second insulating film in an amorphous state by supplying radical oxygen onto the amorphous silicon film, and forming a control gate electrode on the second insulating film.

The invention further provides a method of manufacturing a semiconductor device, comprising forming a trench in a semiconductor substrate, the trench having an inner peripheral wall surface, burying an amorphous silicon film in the trench, forming an insulating film isotropically by supplying radical oxygen onto the amorphous silicon film buried in the trench and onto the inner peripheral wall surface of the trench, and removing, by an anisotropic etching process, the insulating film formed on the amorphous silicon film and forming a collar insulating film on the inner peripheral wall surface of the trench.

### BRIEF DESCRIPTION OF THE DRAWINGS

Other objects, features and advantages of the present invention will become clear upon reviewing the following description of the embodiment with reference to the accompanying drawings, in which:

FIG. 1 is a schematic sectional view of a part of a memory cell region in accordance with a first embodiment of the present invention;

FIG. 2 is a plan view of a part of the memory cell region;

FIG. 3 is a schematic sectional view of a part of the memory cell region at a first step of the manufacturing process;

FIG. 4 is a schematic sectional view of the part of the memory cell region at a second step of the manufacturing process;

FIG. 5 is a graph showing the relationship between a leak current density and a film thickness;

FIG. 6 is a schematic sectional view of the part of the memory cell region at a third step of the manufacturing process;

FIG. 7 is a schematic sectional view of the part of the memory cell region at a fourth step of the manufacturing process;

FIG. 8A is a schematic sectional view of the part of the memory cell region at a fifth step of the manufacturing process;

FIG. 8B is a view explaining a defective;

FIG. 9 is a schematic sectional view of a part of a memory cell region in accordance with a second embodiment of the present invention;

FIG. 10 is a plan view of a part of the memory cell region;

FIG. 11 is a schematic sectional view of a part of the memory cell region at a first step of the manufacturing process;

FIG. 12 is a schematic sectional view of the part of the memory cell region at a second step of the manufacturing process;

FIG. 13 is a schematic sectional view of the part of the memory cell region at a third step of the manufacturing process;

FIG. 14 is a schematic sectional view of the part of the memory cell region at a fourth step of the manufacturing process;

FIG. 15 is a schematic sectional view of the part of the memory cell region at a fifth step of the manufacturing process;

FIG. 16A is a schematic sectional view of the part of the memory cell region at a sixth step of the manufacturing process;

FIG. 16B is an enlarged view of the memory cell region shown in FIG. 16A;

FIG. 17A is a schematic sectional view of the part of the memory cell region at a seventh step of the manufacturing process;

FIG. 17B is a view explaining a defective;

FIG. 18 is a schematic sectional view of the part of the memory cell region at an eighth step of the manufacturing process;

FIG. 19 is a schematic sectional view of the part of the memory cell region at a ninth step of the manufacturing process;

FIG. 20 is a schematic sectional view of the part of the memory cell region at a tenth step of the manufacturing process;

FIG. 21 is a schematic sectional view of the part of the memory cell region at an eleventh step of the manufacturing process;

FIG. 22 is a schematic sectional view of the part of the memory cell region at a twelfth step of the manufacturing process;

FIG. 23 is a schematic sectional view of the part of the memory cell region at a thirteenth step of the manufacturing process;

FIG. 24 is a schematic sectional view of the part of the memory cell region at a fourteenth step of the manufacturing process;

FIG. 25A is a schematic sectional view of the part of the memory cell region at a fifteenth step of the manufacturing process;

FIG. 25B is a view explaining a defective; and

FIG. 26 is a schematic sectional view of the part of the memory cell region at a sixteenth step of the manufacturing process.

### DETAILED DESCRIPTION OF THE INVENTION

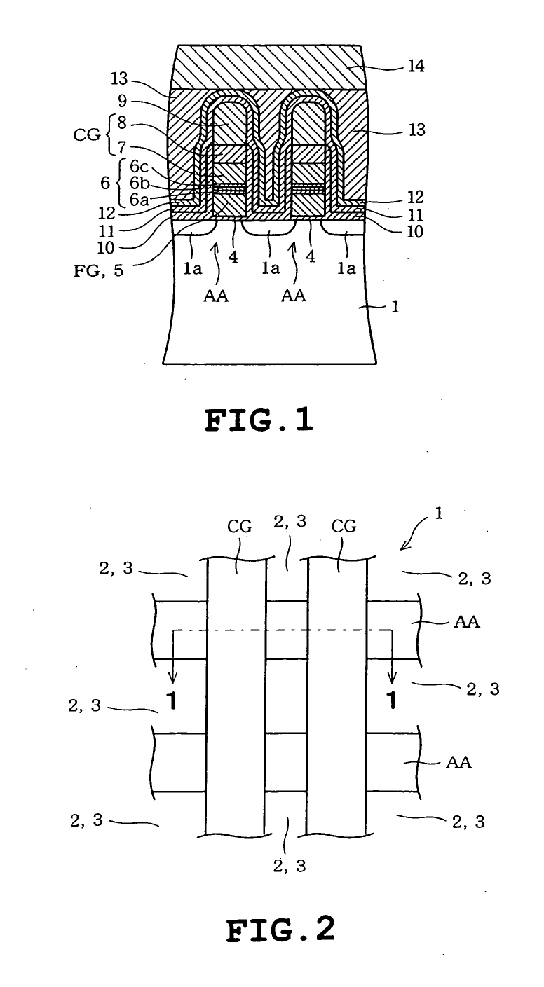

One embodiment of the present invention will be described with reference to FIGS. 1 to 8. The invention is applied to a NAND flash memory in the embodiment.

FIG. 2 shows a major part of a memory cell region of the NAND flash memory is shown. FIG. 1 is a sectional view taken along line 1A-1A in FIG. 2. Referring FIGS. 1 and 2, a silicon substrate 1 serving as a semiconductor substrate is formed with a shallow trench isolation (STI) 2 serving as an element isolation region. An active area AA is defined by the STI 2. Although the memory cell region is shown in the drawings in the embodiment, the NAND flash memory includes a peripheral circuit region in which a peripheral circuit is provided for driving the memory cell transistor as well as the aforementioned memory cell region.

The STI 2 is formed by etching (recessing) the substrate 1 so that a predetermined depth is reached and burying an insulating film 3 in the trench. The active area AA has an upper surface on which a first gate insulating film 4 comprising a silicon oxide film formed by thermal oxidation. An amorphous silicon film 5 doped with impurities such as phosphor is formed on the first gate insulating film 4. The amorphous silicon film 5 serves as a floating gate electrode FG.

A second gate electrode 6 is formed on the amorphous silicon film 5. The second gate insulating film 6 includes a silicon oxide film 6a formed by supplying radical oxygen, a silicon nitride film 6b formed on the silicon oxide film 6a and a silicon oxide film 6c formed on the silicon nitride film 6b. Thus, the second gate insulating film 6 is composed into a composite film with three layers and functions as a intergate insulating film between the floating gate electrode FG and control gate electrode CG. An amorphous silicon film 7 is formed on the second gate insulating film 6. A tungsten silicide film 8 is formed on the amorphous silicon film 7. The amorphous silicon film 7 and the tungsten silicide film 8 constitute a control gate electrode CG.

A silicon nitride film 9 is formed on the control gate electrode CG. An oxide film 10 is formed on outer side walls of the amorphous silicon film 5, second gate insulating film 6, amorphous silicon film 7 and tungsten silicide film 8. The oxide film 10 is formed by supplying radical oxygen, so as to be formed on the sidewalls of the films 5 to 8. A silicon oxide film 11 is formed so as to cover outer surfaces of the oxide film 10 and the silicon nitride film 9. The silicon oxide film 11 is formed for the purpose of reliability securement. Furthermore, a silicon nitride film 12 is formed so as to cover the silicon oxide film 11.

A silicon oxide film 13 is buried between two neighboring gate electrodes (between the floating gate electrodes FG; and between the control gate electrodes CG). The silicon oxide film 13 includes a lower side which is formed so as to be covered by the silicon nitride film 12. The silicon nitride and oxide films 12 and 13 has respective upper surfaces which are substantially co-planar. Furthermore, the upper surfaces of the silicon nitride and oxide films 12 and 13 are planarized, and an interlayer insulating film 14 is formed on the upper layers. The NAND flash memory further includes wiring electrode films and other elements as well as the above-described arrangement. Since the silicon nitride and oxide films 12 and 13 are known in the art, the description of the wiring electrode films and other elements will be eliminated.

### Manufacturing Method

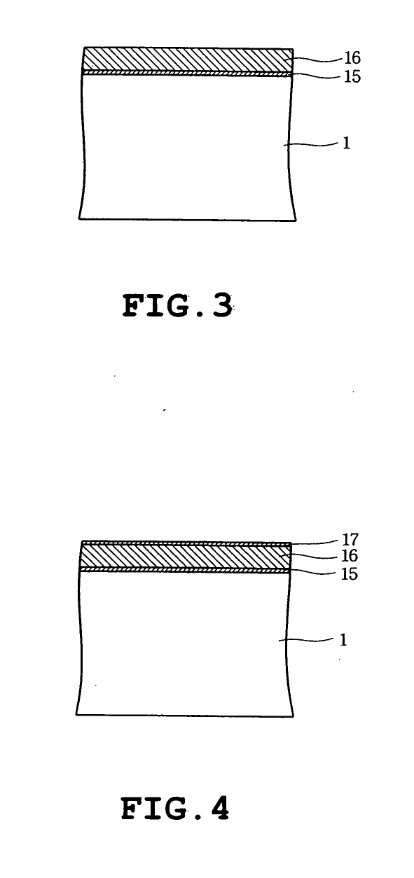

A method of manufacturing the memory cell of the flash memory will now be described with additional reference to FIGS. 3 to 7. In order that the first gate insulating film 4 may be formed as a tunnel oxide film on the silicon substrate 11, a silicon oxide film 15 is formed by a thermal oxidation step so as to ha a film thickness of about 8 nm, as shown in FIG. 3. Next, the amorphous silicon film 16 with a film thickness of about 100 nm is formed on the silicon oxide film 15 by a low pressure chemical vapor deposition (LP-CVD) process. The amorphous silicon film 16 constitutes a floating gate electrode FG. Since the embodiment is characterized by the manufacturing process of the memory cell region, a manufacturing process of the peripheral circuit region will be eliminated. More specifically, a forming step of a thick gate electrode film constituting a high breakdown voltage transistor to be formed in the peripheral circuit region will be eliminated.

Referring now to FIG. 4, a silicon oxide film 17 is formed on the amorphous silicon film 16 so as to have a film thickness of about 4 nm. The silicon oxide film 17 is generally formed by oxidation by heating at about 850° C. or by chemical vapor deposition (CVD) process. In the embodiment, however, radical oxygen is supplied onto the amorphous silicon film 16 so that a silicon oxide film 17 (corresponding to the silicon oxide film 6a in FIG. 1 and to an insulating film in the invention) is formed. In the embodiment, an upper surface of the amorphous silicon film 5 corresponds to a principal surface in the invention.

Method of Forming Silicon Oxide Film 17 (Silicon Oxide Film 6a)

More specifically, the radical oxygen is supplied to be formed into the silicon oxide film 17 in the following manner. O₂ gas serving as a source gas of radical oxygen and Ar gas serving as carrier gas are simultaneously supplied into a chamber. The gas contained in the chamber is excited by microwaves so that radical oxygen is produced. In this case, the pressure in the chamber is set at 1 Torr and microwave power is set at 3500 W. Next, heat is applied to the backside of the silicon by a resistance heater at a temperature below a crystallization temperature of amorphous silicon (constant temperature ranging from 200° C. to 700° C. or more specifically, ranging from 200° C. to 600° C., for example, 400° C.). In this state, radical oxygen is supplied so that the silicon oxide film 17 is made.

Experimental Result of Leak Current Characteristic

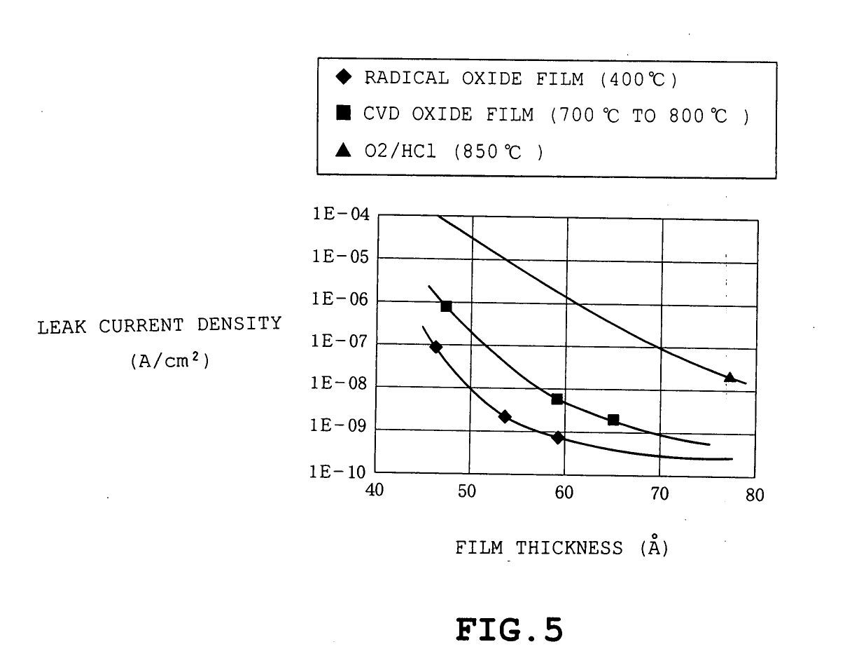

FIG. 5 shows results of an experiment conducted for measurement of leak current flowing into the silicon oxide film formed on the amorphous silicon film. In FIG. 5, an axis of abscissas denotes a film thickness of the silicon oxide film in A and an axis of ordinates denotes density (A/cm²) of leak current caused when an electric field of 6 MV/cm is applied to the silicon oxide film. FIG. 5 also shows leak current characteristic of a thermal oxide film. The oxide film is obtained by heating in an atmosphere of oxygen at 850° C. FIG. 5 further shows the leak current characteristic of an oxide film formed by the CVD process. In measurement of leak current characteristic of an oxide film formed by the CVD process, dichlorosilane and N₂O were used as source gases and a constant temperature ranged from about 700° C. to 800° C.

As shown in FIG. 5, when the silicon oxide film was formed so as to have a film thickness of several tens Å (for example, a constant film thickness ranging from 40 to 80 Å or 40 to 60 Å), an oxide film formed by radical oxidation has lower leak current density than an oxide film formed by thermal oxidation and CVD process. The reason for this is that when the amorphous silicon film is radically oxidized at a low temperature, crystallization of the amorphous silicon film can be suppressed and accordingly the forming of protrusions on a crystal interface can be suppressed, whereupon the interface is almost planarized. On the contrary, the surface of the oxide film formed by thermal oxidation or the CVD method is roughened particularly due to bad temperature condition, whereupon local leak current becomes easy to flow and accordingly an amount of leak current is increased.

It is confirmed by experiment that when the above-described radical oxidation is used, an oxide film can be formed while a film thickness is not less than 20 Å or ranges from 30 Å to 150 Å. Furthermore, it is also confirmed that an interface between the amorphous silicon film and an oxide film formed in an amorphous state by the radical oxidation process can be formed so as to have irregularities not greater than 10 nm and accordingly a substantially smooth state. As a result, the leak current density can be suppressed, and desired characteristics can easily be obtained from the configured semiconductor device.

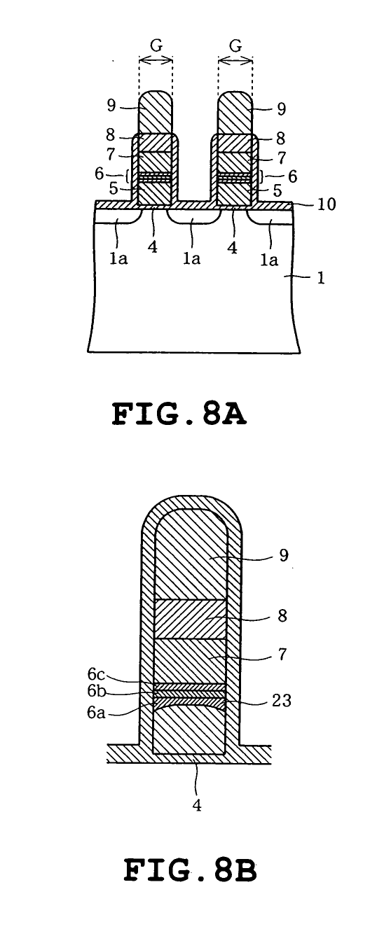

Conventionally, a cleaning technique and the CVD process are used when the silicon oxide film 17 is formed. However, even when a chemical oxide film is made by the cleaning technique, a film thickness is about 10 Å at the most. Thus, a film thickness necessary for a semiconductor device cannot be obtained and accordingly, it is difficult to use a chemical oxide film. Furthermore, for example, when the silicon oxide film 17 is formed by the CVD process, a large bird beak 23 (see FIG. 8B) would sometimes be produced in the amorphous silicon film 5 formed in a layer beneath the silicon oxide film by the assist of water absorbed by the silicon oxide film 6a. However, when the manufacturing method of the embodiment is carried out, an amount of water in the silicon oxide film 6a is reduced. As a result, occurrence of bird beak can be suppressed. As shown in FIG. 4, the silicon oxide film 17 is formed under these conditions.

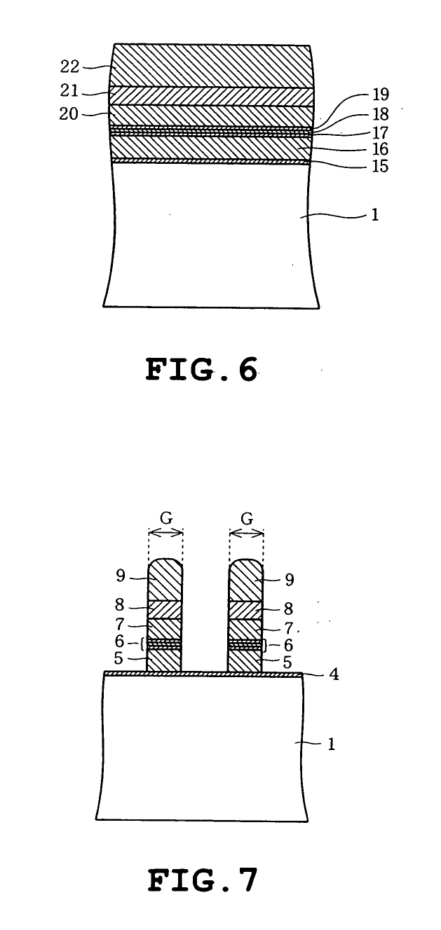

Thereafter, as shown in FIG. 6, a silicon nitride film 18 is formed on the silicon oxide film 17 so as to have a film thickness of 100 Å, and a silicon oxide film 19 is formed on the silicon nitride film 18 so as to have a film thickness of about 50 Å. Next, an amorphous silicon film 20 with a film thickness of about 100 Å is formed to compose a control gate electrode CG. A tungsten silicide film 21 with a film thickness of about 1000 Å is formed on the amorphous silicon film 20 by a sputtering process.

Subsequently, a silicon nitride film 22 with a film thickness of about 2000 amorphous silicon film 20 is formed. The silicon nitride film 22 functions as a cap film on the control gate electrode CG and also serves as a mask in the forming of the control gate electrode CG by the RIE process. Next, resist (not shown) is applied to the silicon nitride film 22 and patterned so that the silicon nitride film 22 is processed. Successively, the tungsten silicide film 21, amorphous silicon film 20, silicon oxide film 19, silicon nitride film 18, silicon oxide film 17 and amorphous silicon film 16 are processed. In this case, the amorphous silicon film 16 remains as the amorphous silicon film 5 in predetermined gate electrode formation regions G as shown in FIG. 7. In the same manner, the films 17 to 19 remains as the second gate insulating film 6 in the predetermined gate electrode formation regions G. The amorphous silicon film 20 remains as the amorphous silicon film 7. The tungsten silicide film 21 remains as the tungsten silicide film 8. The silicon nitride film 22 remains as the silicon nitride film 9.

Next, a radical oxidation process is applied so that outer side walls of the films 6 to 8 are oxidized, whereby a silicon oxide film 10 is formed and the film thickness of the silicon oxide film 15 formed on the silicon substrate 1 is increased. Since the conditions of the radical oxidation in this case are substantially the same as described above, the detailed description of the conditions will be eliminated. Subsequently, a source/drain diffusion layer 1a of the transistor is formed and the silicon oxide film 11 is formed over the entire substrate for securement of reliability. The silicon cover 12 is then formed over the entire substrate so as to cover the control gate electrodes CG and the floating gate electrodes FG. Subsequently, interlayer insulating films, contact plugs, upper layer wiring and the like none of which are shown are formed. However, since these are formed by ordinary methods, the description of the methods will be eliminated.

According to the manufacturing method of the embodiment, radical oxygen is supplied onto the amorphous silicon film 16 so that the silicon oxide film 17 is formed. Consequently, the interface between the amorphous silicon film 16 and the silicon oxide film 17 can be planarized. Moreover, since the supply of radical oxygen is carried out at a temperature lower than the crystallization temperature, the interface can further be planarized.

The silicon oxide film 15 is formed on the silicon substrate 1, and the amorphous silicon film 16 is formed as the floating gate electrode FG on the silicon oxide film 15. Radical oxygen is supplied onto the amorphous silicon film 16 so that the silicon oxide film 17 is formed as a part of the second gate insulating film 6. The silicon oxide film 17 is thereafter recessed. This arrangement can reduce the density of leak current flowing into the silicon oxide film 6a formed on the amorphous silicon film 5 corresponding to the amorphous silicon film 16. Moreover, the above-described method can suppress occurrence of bird beak as compared with a film formed by the CVD process.

The silicon oxide film 17 is formed on the amorphous silicon film 16 by the radical oxidation process. The silicon nitride film 18 is formed on the silicon oxide film 17, and the silicon oxide film 19 is formed on the silicon nitride film 18. Thereafter, the recessing is carried out so that the second gate insulating film 6 is formed as a composite film and a multilayered film. This arrangement can reduce the density of leak current flowing through the interface between the amorphous silicon film 5 and the silicon oxide film 6a. Accordingly, the second gate insulating film 6 comprising a composite film can easily be formed on the amorphous silicon film 5.

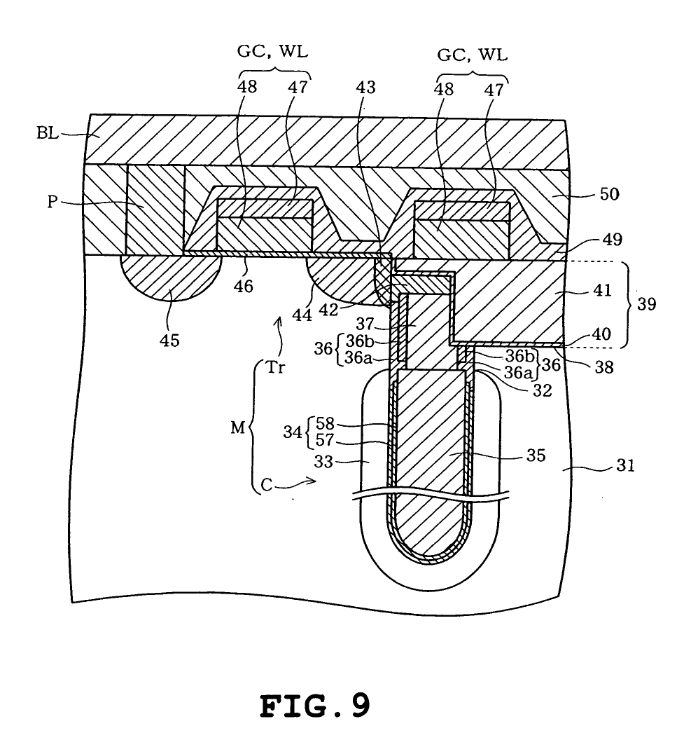

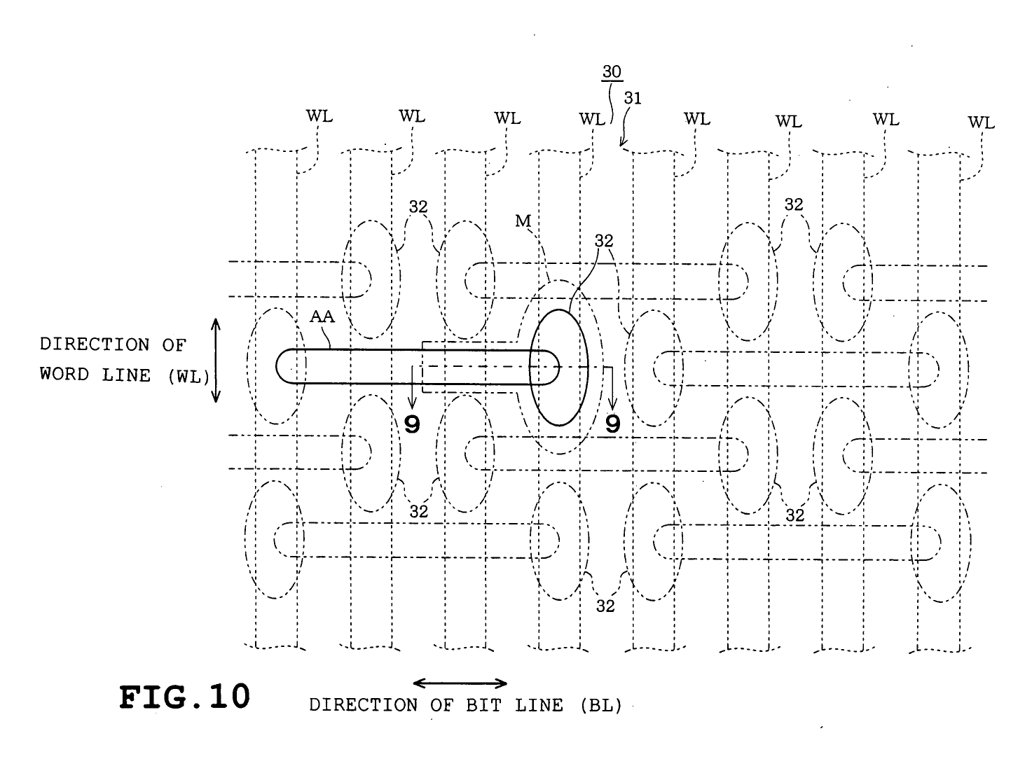

FIGS. 9 to 24 illustrate a second embodiment of the invention. The second embodiment differs from the first embodiment in that the invention is applied to a semiconductor device formed with a trench capacitor type dynamic random access memory (DRAM) cell. FIGS. 9 and 10 are a schematic longitudinally sectional view and a plan view of the DRAM (semiconductor memory device) provided with trench capacitor type DRAM cells. Although the memory cells are formed on a p-type silicon semiconductor substrate 31 (corresponding to a semiconductor substrate) in the second embodiment, the memory cells may be formed in a p-well region at need, instead.

### Structure

FIG. 10 is a schematic plan view showing an arrangement of the memory cell in a memory cell region of the DRAM. FIG. 9 is a schematic sectional view taken along line 9-9 in FIG. 10, showing an internal structure of a memory cell of the DRAM.

The DRAM 30 is provided with a memory cell region in which a plurality of memory cells M are arranged on the silicon substrate 31, as shown in FIG. 10. Trenches 32 are provided in a zigzag arrangement in the memory cell region. Each trench 32 is formed into the shape of an elliptic cylinder.

The structure of one of unit memory cells M will be described. The memory cell M comprises one trench capacitor C and one metal oxide semiconductor (MOS) memory cell transistor Tr as shown in FIG. 9. A deep trench 32 is formed in the silicon substrate 31. A trench capacitor C is formed in a deep interior of the trench 32. Describing the structure of the trench capacitor C, a plate diffusion layer 33 is formed on an outer periphery of the trench at the deep side so as to reach a predetermined level. The plate diffusion layer 33 functions as a plate electrode of the trench capacitor C composing the memory cell M. A capacitor insulating film 34 is formed on an inner periphery at the deep side of the trench 32 and on the plate diffusion layer 33. The capacitor insulating film 34 may be an SiN—SiO₂ film, Al₂O₃—SiO₂ film, HfO₂—SiO₂ film or the like. In the embodiment, the SiN—SiO₂ is employed as the capacitor insulating film 34. The capacitor insulating film 34 includes a silicon nitride film 57 formed on the inner periphery at the deep side of the trench 32 and a silicon oxide film 58 formed by oxidizing the silicon nitride film 57. The capacitor insulating film 34 functions as an insulating film for isolating both plate electrodes of the capacitor C.

A first amorphous silicon film 35 is formed in the interior of the trench 32 so as to be located inside the capacitor insulating film 34. The first amorphous silicon film 35 is made from amorphous silicon doped with impurities such as arsenic (As) and functions as a plate electrode of the trench capacitor C. A sidewall insulating film 36 (corresponding to a collar insulating film) is formed on the inner periphery of the trench 32 so as to be located over the capacitor insulating film 34 and the first amorphous silicon film 35. A radical oxidizing process is applied to an outer wall side insulating film 36a constituting the sidewall insulating film 36 so that the insulating film 36a is formed in an amorphous state. Furthermore, an inner insulating film 36b of the sidewall insulating film 36 is formed by a chemical vapor deposition (CVD) process. The sidewall insulating film 36 is provided for suppressing leak current of a vertical parasitic transistor (not shown). Upon the radical oxidizing process, a contact interface between the capacitor insulating film 34 and the sidewall insulating film 36 is substantially planarized so that the interface has irregularities not greater than 10 nm.

The sidewall insulating film 36 has conventionally been formed at high temperature (900° C., for example) by the CVD process so as to have a large film thickness. It has been difficult to oxidize the silicon nitride film 57 during the formation of the sidewall insulating film 36, and void has occurred. In the embodiment, however, the radical oxidizing process is applied to the outer insulating film 36a of the sidewall insulating film 36. As a result, the outer insulating film 36a can be formed without occurrence of void and accordingly, deterioration in the isolation voltage of the capacitor insulating film 34 can be suppressed.

A second amorphous silicon film 37 is formed over the first amorphous silicon film 35 so as to be located inside the sidewall insulating film 36. The second amorphous silicon film 37 is also made from amorphous silicon doped with impurities such as As. A third amorphous silicon film 42 is formed over the second amorphous silicon film 37. An element isolation region 39 with a shallow trench isolation (STI) structure is provided on the third amorphous silicon film 42. The element isolation region 39 has a contact face on which a silicon oxide film 40 (corresponding to an insulating film) is formed so as to extend at least between the second amorphous silicon film 37 and the element isolation region 39 and between the third amorphous silicon film 42 and the element isolation region 39. Radical oxygen is supplied onto a part of the contact face in contact with the second amorphous silicon film 37 so that the silicon oxide film 40 is formed in an amorphous state. The silicon oxide film 40 and the second amorphous silicon film 37 have an interface therebetween which is formed so as to have irregularities having a width that is not greater than 10 nm. Consequently, the interface can be formed into a flat shape as compared with the conventional arrangement and accordingly, leak current can be suppressed as in the first embodiment.

A silicon oxide film 41 is buried in a space defined by the silicon oxide film 40. The silicon oxide film 41 is adapted to function as an element isolation film. The silicon oxide film 41 provides isolation or separation from other conductive layers (for example, a word line WL passing over the element isolation region 39 and neighboring memory cells) Furthermore, the third amorphous silicon film 42 is formed inside the trench 32 so as to be located on the second amorphous silicon film 37 and a part of the sidewall insulating film 36. The third amorphous silicon film 42 is also made from amorphous silicon doped with impurities such as As.

Thus, the trench capacitor C includes the first to third amorphous silicon films 35, 37 and 42, the plate diffusion layer 33 and the capacitor insulating films. The cell transistor Tr is provided so as to be in contact with and electrically connected to the trench capacitor C and formed at a predetermined side with respect to the trench 32 so as to be electrically connected to the trench capacitor C.

Furthermore, a strap 43 is formed on an interface between the third amorphous silicon film 42 buried in the trench 32 and the cell transistor Tr provided on the outer periphery of the trench 32. The strap 43 is formed at the cell transistor Tr side located at upper outer periphery of the trench 42 by diffusing donor type impurities outward from the third amorphous silicon film 42. The cell transistor Tr includes a gate electrode GC functioning as a word line WL, n-type diffusion layers 44 and 45 (source/drain diffusion layer) formed on the surface layer side of the silicon substrate 31 so as to be located on both sides of the gate electrode GC and a gate insulating film 46 (gate oxide film) formed between the silicon substrate 31 and the gate electrode GC. The gate electrode GC is comprised of a polycrystalline silicon film 48 and a metal silicide layer 47 formed over the film 48.

The third amorphous silicon film 42 constituting the trench capacitor C is connected to the diffusion layer 44 so as to be electrically conductive. A contact plug P is connected to the diffusion layer 45 so as to be electrically conductive. A bit line BL located at the upper surface side is connected via the contact plug P to the diffusion layer 45. Furthermore, a gate sidewall insulating film 49 is formed so as to cover the gate electrode GC. An interlayer insulating film 50 is formed so as to electrically isolate the bit line BL and the memory cell M. The memory cell M is thus constituted. Additionally, an active area AA includes the diffusion layers 44 and 45 and a channel region as shown in FIG. 10. The active area AA functions as an active area for the memory cell M.

According to the second embodiment, the interface between the capacitor insulating film 34 and the insulating film 36a of the sidewall insulating film 36 is formed into the irregularities which are not greater than 10 nm. Consequently, occurrence of void 62 can be suppressed and deterioration in the isolation voltage of the capacitor insulating film 34 can be suppressed. Furthermore, leak current can be suppressed since the interfaces between the second and third amorphous silicon films 37 and 42, and the silicon oxide film 40 formed in the element isolation region 39 are formed into the irregularities which are not greater than 10 nm.

### Manufacturing Method

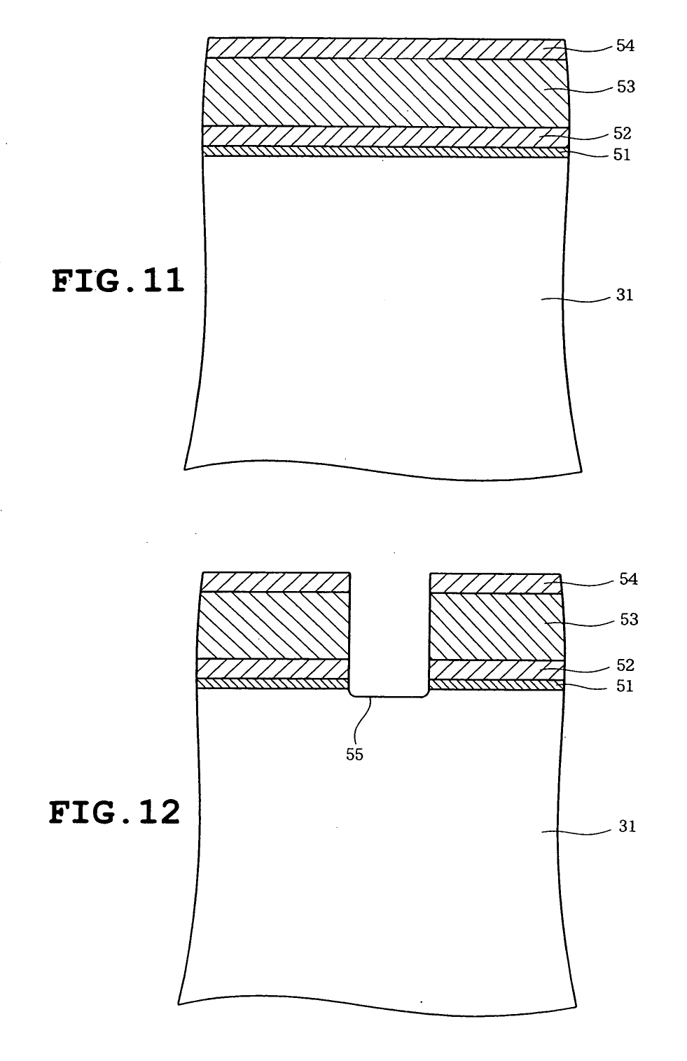

The following describes manufacturing method of the DRAM cell provided with the aforementioned trench capacitor C. FIGS. 11 to 26 are longitudinal sections taken along line 9-9 in FIG. 9, showing sequential steps of the manufacturing process. Referring first to FIG. 10, a silicon oxide film 51 formed on the silicon substrate 31. A silicon nitride film 52 is formed on the silicon oxide film 51. Subsequently, another silicon oxide film 53 doped with impurity such as arsenic (As) is formed on the silicon nitride film 52. Photoresist 54 is applied to the silicon nitride film 52 for the purpose of forming a deep trench and then patterned by the photolithography technique, so that a silicon oxide film 53, silicon nitride film 52 and silicon oxide film 51 are recessed by an anisotropic etching process, whereby a trench 55 is formed. The patterned photoresist 54 is then removed.

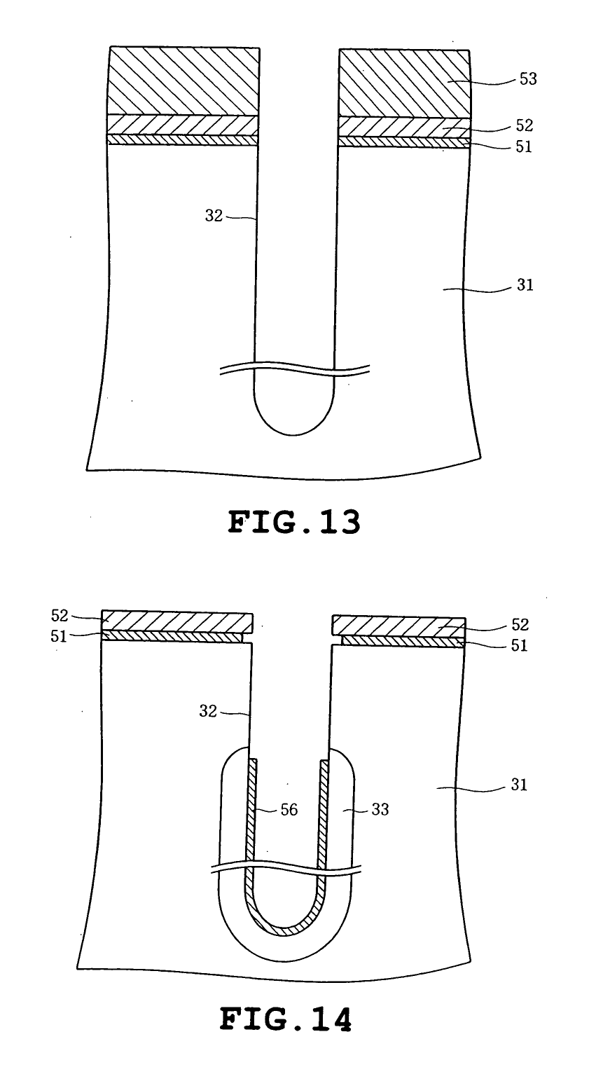

Subsequently, the silicon substrate 31 is recessed by the anisotropic etching process with the silicon oxide film 53 serving as a mask as shown in FIG. 13. As a result, the silicon substrate 31 is recessed until a predetermined depth is reached, whereby the deep trench 55 is formed. The silicon oxide film 53 is then delaminated. Next, an oxide film 56 doped with impurity such as As (hereinafter, referred to as “As-doped oxide film) is formed on inner surfaces of the trench 55 by the CVD process. A lower end of the trench 55 is etched so that a predetermined depth (1.5 μm, for example) from the surface of the silicon substrate 31 is obtained. A thermal treatment at 1000° C. is subsequently carried out so that a plate diffusion layer 33 (n-type diffusion layer) is formed on an outer side of the trench 55. A wet etching process is then carried out so that the As-doped oxide film is delaminated.

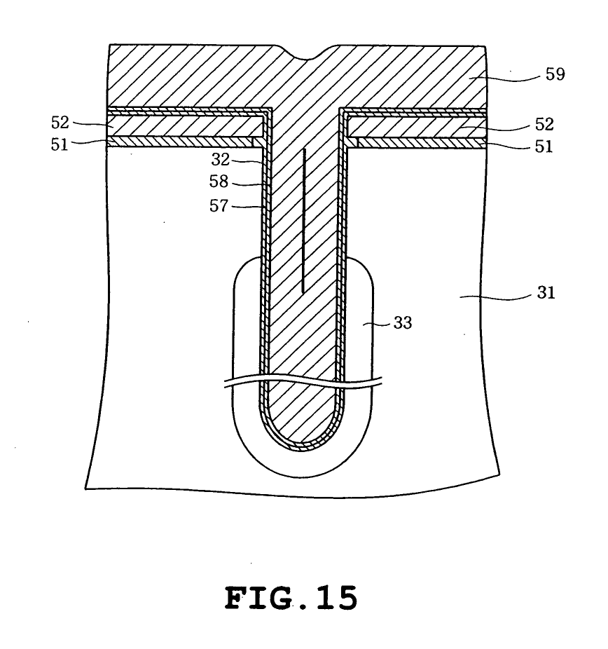

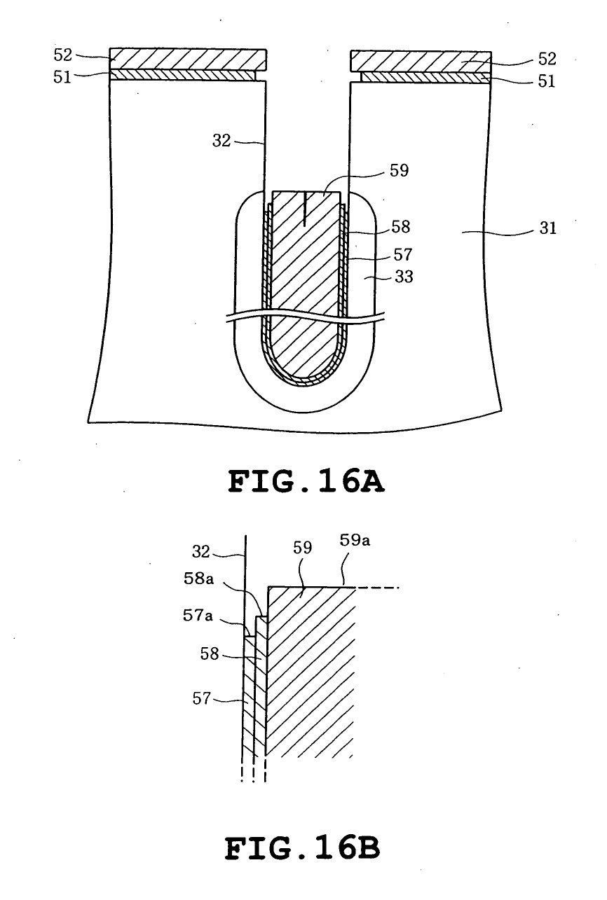

Subsequently, a silicon nitride film 57 is formed by the CVD process as shown in FIG. 15. A surface of the silicon nitride film 57 is oxidized in an atmosphere of dry oxygen thereby to be formed into a silicon oxide film 58. An amorphous silicon film 59 doped with impurity such as As is formed in the trench 32 by the CVD process. Next, the amorphous silicon film 59 is planarized by the CMP process with the silicon nitride film 57 serving as a stopper. The amorphous silicon film 59 is further etched so that a depth of about 1.3 μm from the surface of the silicon substrate 31 is obtained. A wet etching process is carried out for the amorphous silicon film 59 using dilute hydrofluoric acid (DHF). Since the silicon nitride film 57 and the silicon oxide film 58 have different etching rates, an upper end 57a of the silicon nitride film 57 is located deeper than an upper end 58a of the silicon oxide film 58 relative to the surface of the silicon substrate 31, as shown in FIGS. 16A and 16B. Moreover, the upper ends 57a and 58a of the films 57 and 58 are located deeper than an upper end 59a of the amorphous silicon film 59. The amorphous silicon film 59 is formed into the amorphous silicon film 35.

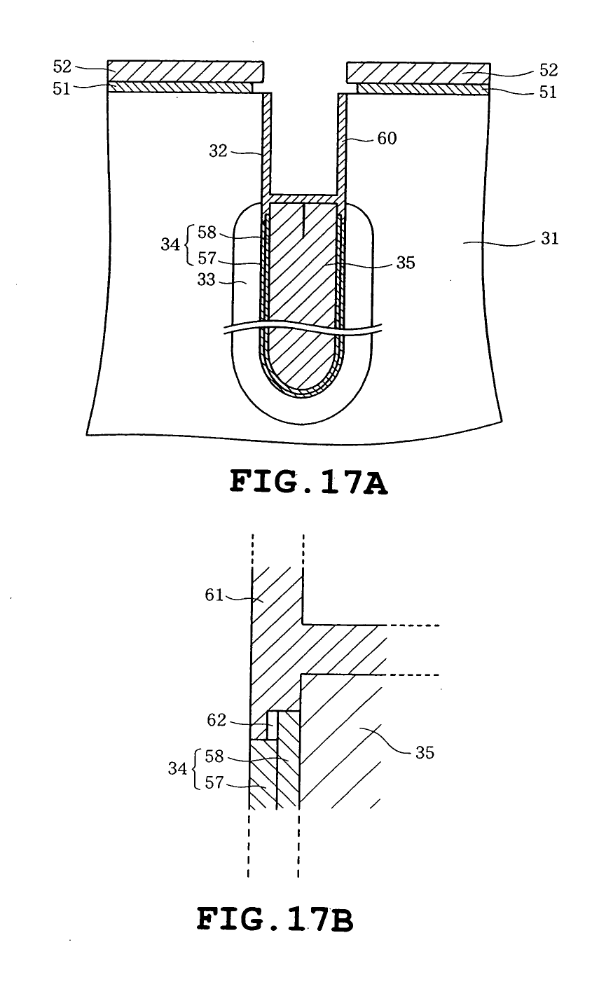

Subsequently, as shown in FIG. 17, a silicon oxide film 60 is formed in the trench 32. More specifically, radical oxygen is supplied into the trench 32 in the same manner as in the forming of the silicon oxide film 17 in the foregoing embodiment, so that the silicon oxide film 60 is formed on the inner surface of the trench 32 and further on the amorphous silicon film 35 isotropically. Further more specifically, a thermal treatment is applied to the backside of the silicon substrate at a temperature lower than a crystallization temperature of amorphous silicon (a constant temperature ranging from 200° C. to 700° C. or a constant temperature ranging from 200° C. to 600° C., for example, 400° C.). In this state, radical oxygen is supplied into the trench 32 so that the silicon oxide film 60 is formed. A supplying period of the radical oxygen is adjusted so that a film thickness of the silicon oxide film 60 is set to 100 Å. As a result, the insulating film 60 is isotropically formed on the inner wall of the trench 32 on the capacitor insulating film 34 and the amorphous silicon film 35 and further over the amorphous silicon film 35.

For example, when an insulating film 61 is isotropically formed by the CVD process on the capacitor insulating film 34 and the amorphous silicon film substantially in the same manner as in the conventional technique, a void 62 occurs between the silicon nitride film 57 and silicon oxide film 58, and the insulating film 60, as shown in FIG. 17B. The occurrence of the void results from the volumetric shrinkage of the amorphous silicon film 35. Upon occurrence of void, an isolation voltage of the capacitor insulating film 34 is deteriorated. In the embodiment, however, the radical oxygen is supplied into the trench 32 so that the insulating film 60 is formed on the sidewall of the trench 32, deterioration in the isolation voltage of the capacitor insulating film 34 can be suppressed.

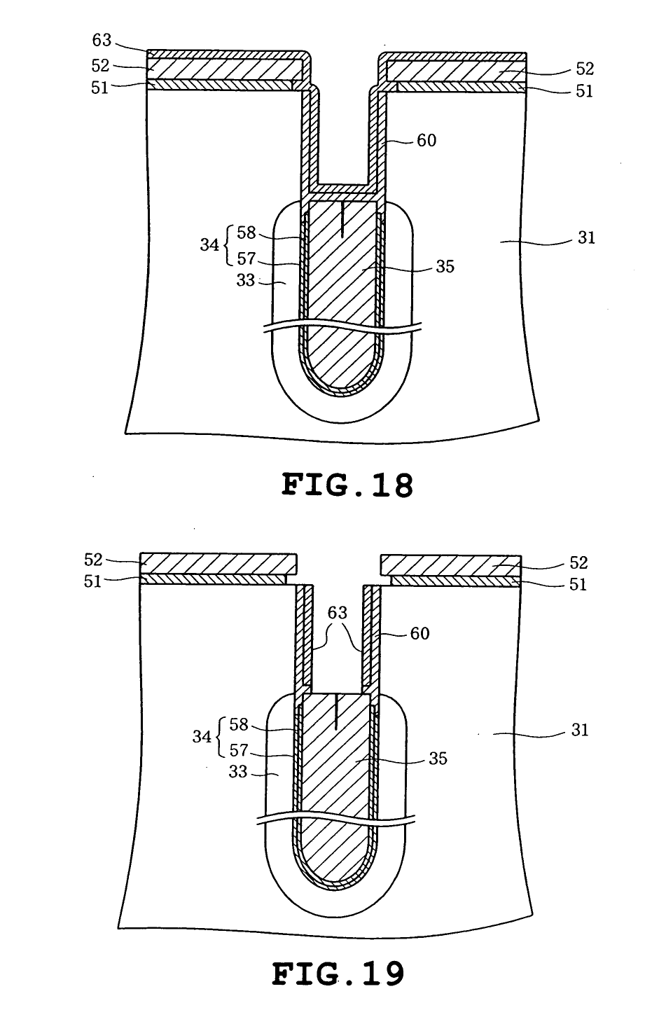

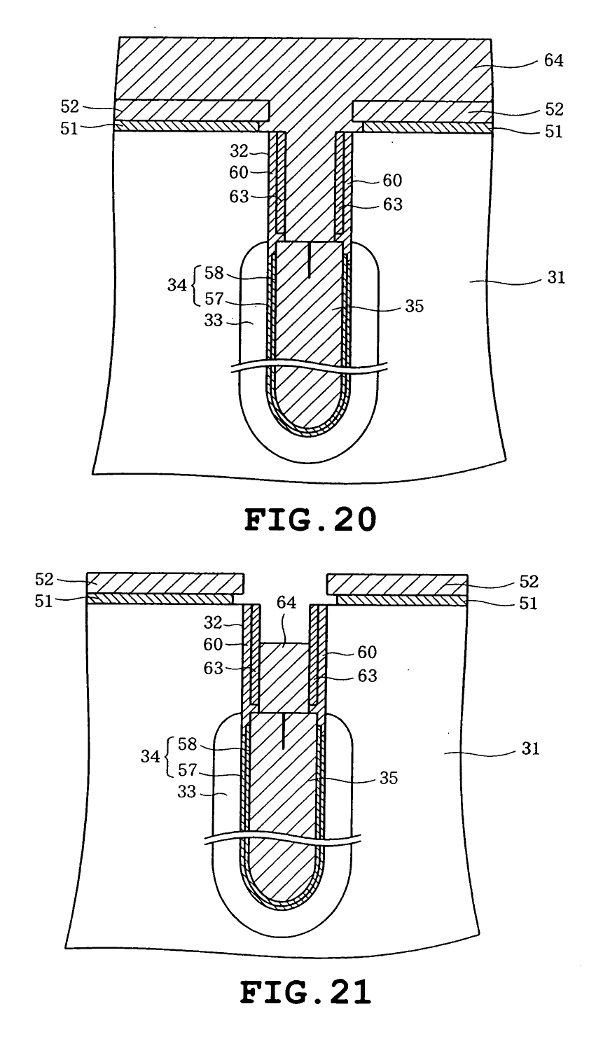

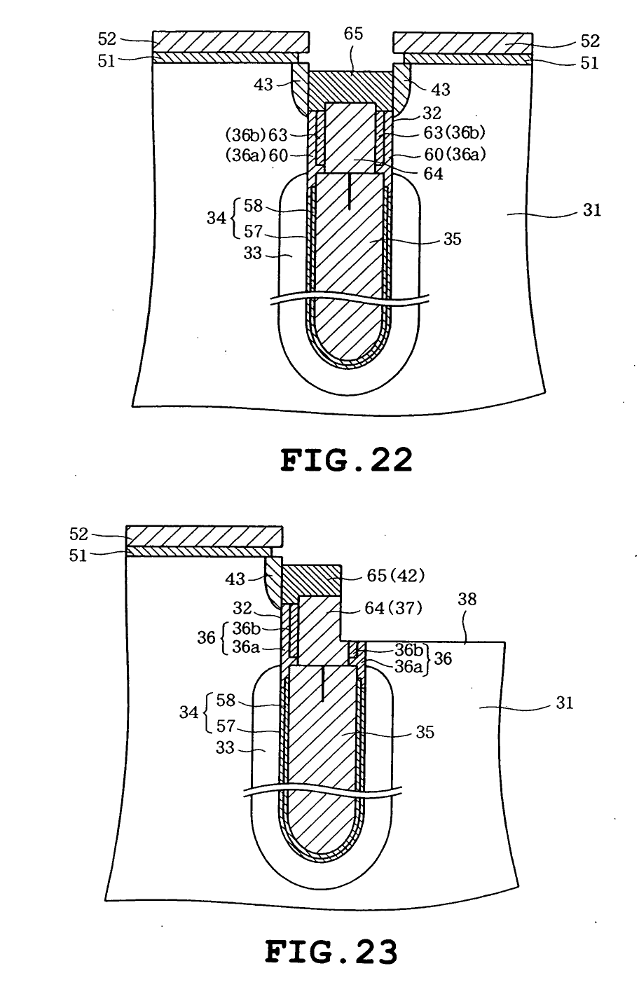

Subsequently, as shown in FIG. 18, a silicon oxide film 63 is isotropically formed in the trench 32 by the CVD process. This can increase a film thickness of the silicon oxide film 60 formed on the inner wall of the trench 32. Next, as shown in FIG. 19, the silicon oxide film 63 and silicon oxide film 60 both formed on the amorphous silicon film 35 are etched by the RIE process thereby to be removed. Consequently, the silicon oxide film 63 and silicon oxide film 60 remain on the inner wall of the trench 32. Subsequently, as shown in FIG. 20, an amorphous silicon film 64 is buried over the amorphous silicon film 35 further buried in the trench 32. Next, as shown in FIG. 21, the amorphous silicon film 64 is etched back so that a surface thereof is located slightly deeper than the surface of the silicon substrate 31. Then, as shown in FIG. 22, an isotropic etching process is carried out so that the silicon oxide films 63 and 60 formed on the upper sidewall of the film 64 in the trench 32 is selectively removed, whereby the collar oxide film 36 is formed. Furthermore, an amorphous silicon film 65 is buried on the amorphous silicon film 64 and the collar oxide film 36. The amorphous silicon film 65 is then etched back so that an upper surface thereof is located near to the surface of the silicon substrate 32.

Subsequently, for example, germanium (Ge) is doped to an interface between the trench 32 and the silicon substrate 31 from over the trench 32 for the purpose of adjustment of a threshold (threshold voltage) of the cell transistor Tr. Thermal treatment is carried out a high temperature so that donor impurity is diffused outward from the amorphous silicon film 65, whereupon a strap 43 is formed. The strap 43 is provided for suppressing electrical resistance between the diffusion layer 44 of the cell transistor Tr and the trench capacitor C.

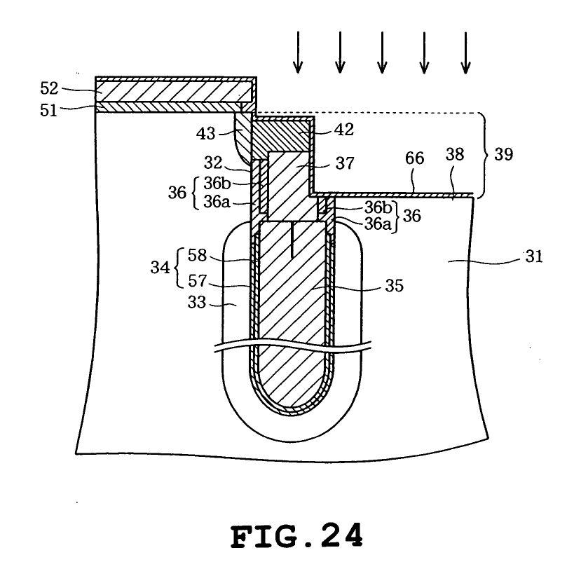

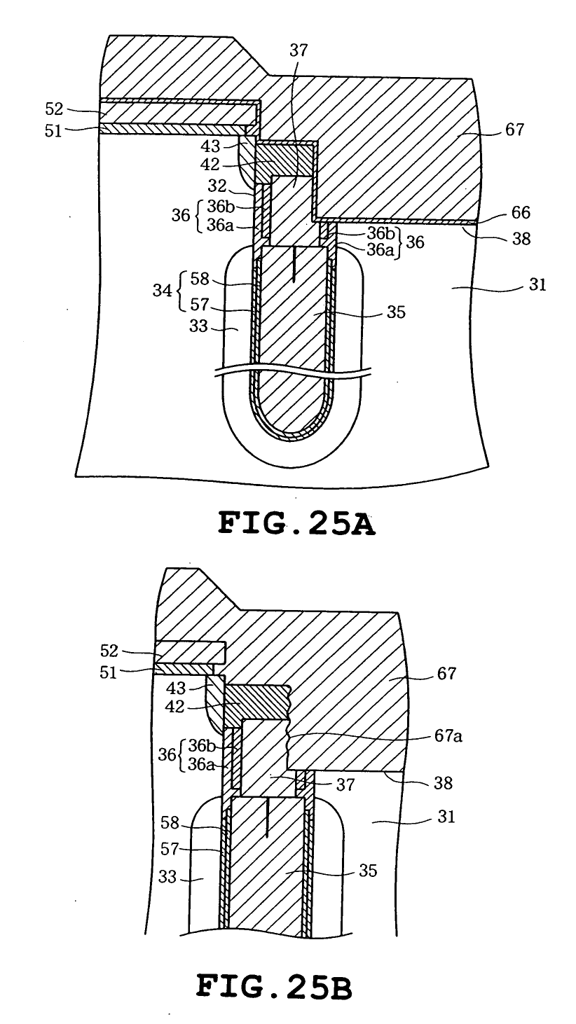

Subsequently, resist (not shown) is applied and a resist pattern is formed by the photolithograph technique, and thereafter, a trench 38 is formed in the amorphous silicon films 65 and 64 and the sidewall insulating film 36 by an anisotropic etching process, as shown in FIG. 23. In this step, the trench 38 is formed so as to have a predetermined depth from the surface of the silicon substrate 31 for the purpose of formation of the element isolation region 39 against the neighboring memory cell (not shown). Next, as shown in FIG. 24, radical oxygen is supplied into the trench 38 so that a silicon oxide film 66 is isotropically formed for improvement in the reliability of the device. Since an oxidation condition is substantially the same as the aforementioned condition of radical oxidation, the description of the oxidation condition will be eliminated. Next, as shown in FIG. 25A, a silicon oxide film 67 is deposited on the silicon oxide film 66.

The sidewalls of the amorphous silicon films 64 and 65 (37 and 42) buried in the trench 32 and the upper surface of the amorphous silicon film 65 (42) are exposed. Accordingly, these portions are also oxidated in the above-described radical oxidation step. A thermal oxidation process is conventionally employed for oxidation of the aforementioned portions. It is known that an oxidizing rate has a crystal orientation dependency or an impurity density dependency in the aforementioned thermal oxidation process particularly when an amorphous silicon film is oxidized into a polycrystalline silicon film. Upon execution of the oxidation process, a plurality of trench capacitors C have different crystal orientations of the polycrystalline silicon films. Furthermore, different crystalline orientations according to a direction of interface even in each one trench capacitor C are exposed on the sidewalls. Accordingly, the sidewall obtained after oxidation of an amorphous silicon film (polycrystalline silicon film) has different irregularities. This solid difference results in sectional area difference and causes variations in the interface resistance.

More specifically, as shown in FIG. 25B, when the silicon oxide film 67 is deposited in a conventional method, coarse irregularities occur in an interface between the silicon oxide film 67, and amorphous silicon films 64 and 65 (37 and 42). When the coarse irregularities occur, there is a possibility of outward diffusion of impurity doped in the amorphous silicon films 64 and 65 (37 and 42) or solid phase diffusion to the silicon substrate 31. The resistance value is increased when impurity density in the amorphous silicon films 64 and 65 (37 and 42) is reduced. The increase in the resistance value results in adverse effects on the characteristics of the trench capacitor C. Furthermore, the adverse effects of the solid phase diffusion to the silicon substrate 31 render the effective gate length shorter, thereby worsening a short-channel effect.

In the embodiment, however, the radical oxidation process is firstly carried out so that the silicon oxide film 66 is formed, and thereafter, the silicon oxide film 67 is deposited. In this forming method, the contact interface between the amorphous silicon films 64 and 65 (37 and 42) and the silicon oxide film 66 is formed so that a maximum width is not more than 10 nm, whereupon the solid difference of each trench capacitor can be suppressed. Moreover, the outward diffusion of impurities from the amorphous silicon films 64 and 65 (37 and 42) can be suppressed and ion diffusion to the silicon substrate 31 can be suppressed.

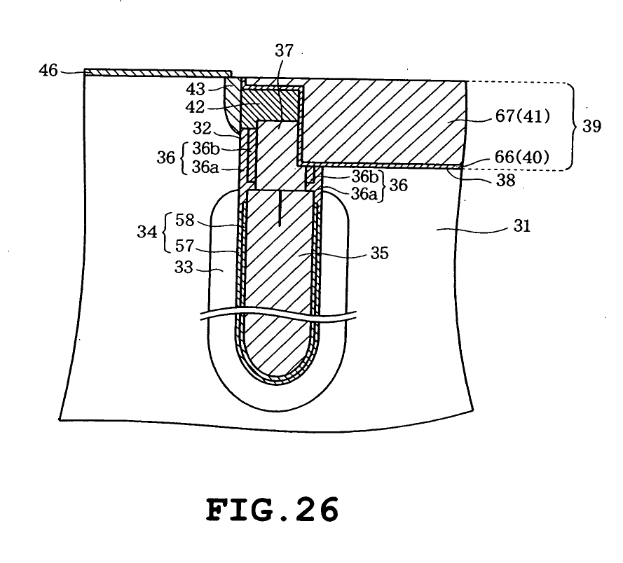

Subsequently, as shown in FIG. 26, the silicon oxide film 67 is etched back so that the surface thereof is located near the surface of the silicon substrate 31, and the gate insulating film 46 is formed. Subsequently, as shown in FIG. 9, the gate electrode GC (polycrystalline silicon film 48 and metal silicide layer 47), diffusion layers 44 and 45 of the cell transistor Tr are formed. The gate sidewall insulating film 49 is formed so as to cover the gate electrode GC. The interlayer insulating film 50 is further formed on the gate sidewall insulating film 49. Subsequently, a contact plug P is buried in the interlayer insulating film 50, and the bit line BL and the like are formed over the contact plug P and the interlayer insulating film 50. Thus, the DRAM semiconductor device 30 can be manufactured through the above-described steps.

According to the manufacturing method, radical oxygen is supplied onto the silicon nitride film 57 and silicon oxide film 58 formed on the inner wall located deep in the trench 32 so that the insulating film 60 is formed. The insulating film 60 formed on the amorphous silicon film 35 is removed by the anisotropic etching process so that the collar insulating film 36a is formed on the inner wall of the trench 32. Consequently, since occurrence of void 62 is prevented in the interface between the collar insulating film 36a and the capacitor insulating film 34, the isolation voltage of the capacitor insulating film 34 can be prevented from deterioration.

Furthermore, the trench 38 for element isolation is formed in the side of the amorphous silicon film 37 buried in the trench 32. The radical oxygen is supplied into the trench 38 so that the insulating film 40 (66) is formed on the exposed surface of the amorphous silicon film 37. As a result, the interface between the amorphous silicon films 64 and 65 (37 and 42) and the silicon oxide film 66 (40) can be formed so as to have the irregularities not greater than 10 nm. Consequently, the solid difference of each trench capacitor C can be suppressed. Moreover, outward diffusion of the impurity from the amorphous silicon films 64 and 65 (37 and 42) can be suppressed, and solid phase diffusion to the silicon substrate can be suppressed.

The invention should not be limited to the foregoing embodiments. The embodiments can be modified or expanded as follows. In the first embodiment, thermal treatment is applied to the backside of the silicon substrate 1 at 400° C. and in this state, radical oxygen is supplied into the trench. However, the temperature of the thermal treatment may range from 200° C. to 700° C.

In the first embodiment, microwaves are excited on the condition of chamber pressure at 1 Torr so that the radical oxygen is produced to be supplied. However, for example, the applied pressure may range from 0.05 Torr to 2 Torr.

An O₂ gas and Ar gas are employed as the source gas and carrier gas respectively in the first embodiment. However, for example, only O₂ gas, O₂/H₂ gas, O₂/Ne gas, O₂/Kr gas, O₂/H₂/Ne gas, O₂/H₂/Ar gas or O₂/H₂/Kr gas may be used, instead.

The invention is applied to the DRAM 30 in the foregoing embodiment. However, the invention may be applied to other DRAM devices such as general-purpose DRAM devices.

The foregoing description and drawings are merely illustrative of the principles of the present invention and are not to be construed in a limiting sense. Various changes and modifications will become apparent to those of ordinary skill in the art. All such changes and modifications are seen to fall within the scope of the invention as defined by the appended claims.

What is claimed is:

1. A semiconductor device comprising:
an amorphous silicon film having a principal plane; and
an insulating film formed by supplying radical oxygen onto the principal plane of the amorphous silicon film.

2. The semiconductor device according to claim 1, wherein an interface between the amorphous silicon film and the insulating film is formed so as to have irregularities not greater than 10 nm.

3. A method of manufacturing a semiconductor device, comprising:
forming an insulating film by supplying radical oxygen onto a principal surface of an amorphous silicon film at a temperature lower than a crystallization temperature of the amorphous silicon film, the amorphous silicon film constituting the semiconductor device.

4. A method of manufacturing a semiconductor device, comprising:
forming a first insulating film on a semiconductor substrate;
forming an amorphous silicon film serving as a floating gate electrode on the first insulating film; and
forming a second insulating film in an amorphous state by supplying radical oxygen onto the amorphous silicon film; and
forming a control gate electrode on the second insulating film.

5. A method of manufacturing a semiconductor device, comprising:
forming a trench in a semiconductor substrate, the trench having an inner peripheral wall surface;
burying an amorphous silicon film in the trench;
forming an insulating film isotropically by supplying radical oxygen onto the amorphous silicon film buried in the trench and onto the inner peripheral wall surface of the trench; and
removing, by an anisotropic etching process, the insulating film formed on the amorphous silicon film and forming a collar insulating film on the inner peripheral wall surface of the trench.
